(19) United States
(12) Patent Application Publication
(10) Pub. No.: US 2022/0393655 A1
(43) Pub. Date: Dec. 8, 2022

(54) LINEARIZATION USING COMPLEMENTARY DEVICES

(71) Applicant: SKYWORKS SOLUTIONS, INC., Irvine, CA (US)

(72) Inventors: Yu Zhu, Wellesley, MA (US); Oleksiy Klimashov, Burlington, MA (US); Dylan Charles Bartle, Arlington, MA (US); Paul T. DiCarlo, Marlborough, MA (US)

(21) Appl. No.: 17/805,717

(22) Filed: Jun. 7, 2022

Related U.S. Application Data
(60) Provisional application No. 63/197,598, filed on Jun. 7, 2021.

(51) Int. Cl. H03F 3/24; H03F 1/02

(52) U.S. Cl. CPC H03F 3/245; H03F 1/0222; H03F 2200/451

(57) ABSTRACT

According to at least one example of the disclosure, a power amplifier is provided comprising a first power switch of a first type being configured to receive an input signal and provide an amplified output signal to an output connection configured to be coupled to a load, and a second power switch of a second type different than the first type, the second power switch being configured to improve a linearity of the power amplifier and being coupled to the output connection.

### CROSS-REFERENCE TO RELATED APPLICATIONS

This application claims priority under 35 U.S.C. § 119(e) to U.S. Provisional Application Ser. No. 63/197,598, titled “LINEARIZATION USING COMPLEMENTARY DEVICES,” filed on Jun. 7, 2021, which is hereby incorporated by reference in its entirety.

### BACKGROUND

### 1. Field of the Disclosure

At least one example in accordance with the present disclosure relates generally to power amplification.

### 2. Discussion of Related Art

Electronic devices may include one or more power amplifiers. A power amplifier may modulate an input signal, such as by increasing a current and/or voltage of the input signal. Power amplifiers may be used in many types of electrical devices, such as mobile cellular telephones. For example, a mobile cellular device may include an antenna and one or more power amplifiers to amplify a signal transmitted or received via the antenna.

### SUMMARY

According to at least one aspect of the present disclosure, a power amplifier is provided comprising a first power switch of a first type being configured to receive an input signal and provide an amplified output signal to an output connection configured to be coupled to a load, and a second power switch of a second type, different than the first type, the second power switch being configured to improve a linearity of the power amplifier and being coupled to the output connection. In some examples, the first power switch and the second power switch are high-electron-mobility transistors (HEMTs). In various examples, the first type is a depletion-type HEMT and the second type is an enhancement-type HEMT. In at least one example, the first power switch is larger than the second power switch. In some examples, the first power switch is approximately 50 microns and the second power switch is approximately 11 microns. In various examples, the power amplifier further comprises at least one bias-voltage connection to receive at least one bias voltage and provide the at least one bias voltage to the first power switch and the second power switch. In at least one example, the second power switch is configured to improve the linearity of the power amplifier at the at least one bias voltage.

In some examples, improving the linearity of the power amplifier includes reducing at least one of second-order or third-order harmonics in the first power switch. In various examples, the at least one bias-voltage connection includes a single bias-voltage connection coupled to the first power switch and the second power switch. In at least one example, the at least one bias-voltage connection includes a first bias-voltage connection coupled to the first power switch and a second bias-voltage connection coupled to the second power switch. In some examples, the at least one bias voltage includes a first bias voltage provided to the first power switch and a second bias voltage provided to the second power switch.

In various examples, the first bias voltage is different than the second bias voltage. In at least one example, the first bias voltage has a different polarity than the second bias voltage. In some examples, the first power switch is coupled in parallel with the second power switch. In various examples, the power amplifier further comprises an input-signal connection to receive the input signal, and the input signal is provided to a first control connection of the first power switch and to a second control connection of the second power switch to drive the first power switch and the second power switch.

According to aspects of the disclosure, a method of operating a power amplifier is provided comprising coupling an input-signal connection to a first power switch and a second power switch, the input-signal connection being configured to receive an input signal, coupling an output-signal connection to the first power switch, and selecting a size of the second power switch to improve a linearity of the first power switch, the size of the second power switch being different than a size of the first power switch.

In some examples, the method includes selecting the size of the second power switch based on at least one parameter of the input signal. In various examples, the at least one parameter includes at least one of a frequency, a voltage, or a power. In at least one example, the method includes coupling a control connection of the second power switch to a bias-voltage connection, the bias-voltage connection being configured to provide a bias voltage having a value selected to improve the linearity of the first power switch.

According to aspects of the disclosure, a wireless device is provided comprising an antenna to transmit or receive at least one radio-frequency (RF) signal, and a power amplifier configured to amplify the at least one RF signal, the power amplifier comprising a first power switch of a first type being configured to receive the at least one RF signal, amplify the at least one RF signal, and provide the amplified at least one RF signal to an output connection, and a second power switch of a second type different than the first type, the second power switch being configured to improve a linearity of the power amplifier and being coupled to the output connection.

According to aspects of the disclosure, a power-amplifier system is provided comprising a first power amplifier of a first type being configured to receive an input signal and provide an amplified output signal to a load, and a second power amplifier of a second type, the second type being different than the first type and the second power amplifier being configured to improve a linearity of the power-amplifier system.

In some examples, the first power amplifier and the second power amplifier are high-electron-mobility transistors (HEMTs). In various examples, the first type is a depletion-type HEMT and the second type is an enhancement-type HEMT. In at least one example, the first power amplifier is larger than the second power amplifier. In some examples, the first power amplifier is approximately 50 microns and the second power amplifier is approximately 11 microns. In various examples, the power-amplifier system includes at least one bias-voltage connection to receive at least one bias voltage and provide the at least one bias voltage to the first power amplifier and the second power amplifier.

In at least one example, the second power amplifier is configured to improve the linearity of the power-amplifier system at the at least one bias voltage. In some examples, improving the linearity of the power-amplifier system includes reducing at least one of second-order or third-order harmonics in the first power amplifier. In various examples, the at least one bias-voltage connection includes a single bias-voltage connection coupled to the first power amplifier and the second power amplifier. In at least one example, the at least one bias-voltage connection includes a first bias-voltage connection coupled to the first power amplifier and a second bias-voltage connection coupled to the second power amplifier.

In some examples, the at least one bias voltage includes a first bias voltage provided to the first power amplifier and a second bias-voltage connection provided to the second power amplifier. In various examples, the first bias voltage is different than the second bias voltage. In at least one example, the first bias voltage has a different polarity than the second bias voltage. In some examples, the first power amplifier is coupled in parallel with the second power amplifier. In at least one example, the power-amplifier system includes an input-signal connection to receive the input signal, and the input signal is provided to a first control connection of the first power amplifier and to a second control connection of the second power amplifier to drive the first power amplifier and the second power amplifier.

According to aspects of the disclosure, a method of operating a power-amplifier system includes coupling an input-signal connection to a first power amplifier and a second power amplifier, the input-signal connection being configured to receive an input signal, coupling an output-signal connection to the first power amplifier, and selecting a size of the second power amplifier to improve a linearity of the first power amplifier.

In some examples, the method includes selecting a size of the second power amplifier based on at least one parameter of the input signal. In various examples, the at least one parameter includes at least one of a frequency, a voltage, and a power. In at least one example, the method includes coupling a control connection of the second power amplifier to a bias-voltage connection, the bias-voltage connection being configured to provide a bias voltage having a value selected to improve the linearity of the first power amplifier.

According to aspects of the disclosure, a wireless device is provided comprising an antenna to transmit or receive at least one radio-frequency (RF) signal, and a power-amplifier system configured to amplify the at least one RF signal, the power-amplifier system comprising a first power amplifier of a first type being configured to receive the at least one RF signal and amplify the at least one RF signal, and a second power amplifier of a second type, the second type being different than the first type and the second power amplifier being configured to improve a linearity of the power-amplifier system.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a wireless device according to an example;

FIG. 2 illustrates a schematic diagram of a power amplifier according to an example;

FIG. 3 illustrates a graph of third-order harmonics in a transconductance of the power amplifier of FIG. 2 according to an example;

FIG. 4 illustrates a schematic diagram of a power amplifier according to another example;

FIG. 5 illustrates a graph of switch drain currents as a function of gate voltage according to a first example of the power amplifier of FIG. 4;

FIG. 6 illustrates a graph of respective switch transconductances as a function of gate voltage according to the first example;

FIG. 7 illustrates a graph of switch second-order harmonics as a function of gate voltage according to the first example;

FIG. 8 illustrates a graph of switch third-order harmonics as a function of gate voltage according to the first example;

FIG. 9 illustrates a graph of respective switch transconductances as a function of gate voltage according to a second example of the power amplifier of FIG. 4;

FIG. 10 illustrates a graph of switch third-order harmonics as a function of gate voltage according to the second example;

FIG. 11 illustrates a graph of an output power and a third-order intermodulation point as a function of gate voltage at a constant input power according to the second example;

FIG. 12 illustrates a graph of a third-order output intercept point as a function of gate voltage according to the second example;

FIG. 13 illustrates a graph of second-order harmonics and a third-order intermodulation point as a function of gate voltage according to the second example;

FIG. 14 illustrates a graph of a third-order intermodulation point as a function of input power at a constant gate-voltage value according to the second example;

FIG. 15 illustrates a graph of a third-order intermodulation point as a function of input power at a constant gate-voltage value and for various sizes of an EFET according to the second example;

FIG. 16 illustrates a graph of a third-order intermodulation point as a function of input-signal frequency at a constant gate-voltage value and input-power value according to the second example;

FIG. 17 illustrates a schematic diagram of a power amplifier according to another example;

FIG. 18A illustrates a first graph of a third-order intermodulation point as a function of a gate voltage provided to a DFET for a first size of an EFET according to the example of FIG. 17;

FIG. 18B illustrates a second graph of a third-order intermodulation point as a function of a gate voltage provided to the DFET for a second size of the EFET according to the example of FIG. 17;

FIG. 18C illustrates a third graph of a third-order intermodulation point as a function of a gate voltage provided to the DFET for a third size of the EFET according to the example of FIG. 17;

FIG. 18D illustrates a fourth graph of a third-order intermodulation point as a function of a gate voltage provided to the DFET for a fourth size of the EFET according to the example of FIG. 17;

FIG. 18E illustrates a fifth graph of a third-order intermodulation point as a function of a gate voltage provided to the DFET for a fifth size of the EFET according to the example of FIG. 17;

FIG. 18F illustrates a sixth graph of a third-order intermodulation point as a function of a gate voltage provided to the DFET for a sixth size of the EFET according to the example of FIG. 17;

FIG. 19 illustrates a graph of a third-order output intercept point as a function of gate voltage according to the example of FIG. 17; and

FIG. 20 illustrates a graph of a third-order input intercept point as a function of gate voltage (Vg) according to the example of FIG. 17.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

As discussed above, electrical devices may include power amplifiers. Power amplifiers amplify an input signal to produce an amplified output signal. A gain value of the power amplifier indicates a degree to which the input signal is amplified. It may be desirable for the gain value to be constant, or “linear,” as the input signal varies. An ideal power amplifier may be one that is perfectly linear, that is, one for which a gain value does not vary as a function of the input-signal magnitude. In many real systems, however, power amplifiers may not be perfectly linear. For example, higher-order harmonics, such as second- and third-order harmonics, may adversely impact the linearity of a power amplifier.

Examples of the disclosure improve power-amplifier linearity. In one example, a power amplifier includes a primary switch, such as a high-electron-mobility transistor (HEMT). A linearity of the power amplifier may be improved by implementing a second, complementary power switch, such as a complementary HEMT. The complementary HEMT may be selected and/or operated to mitigate properties of the primary HEMT that adversely impact a linearity of the power amplifier. For example, the complementary HEMT may be selected and/or operated to mitigate the effects of higher-order harmonics of the primary HEMT. The complementary HEMT may therefore improve an overall linearity of the power amplifier by balancing (for example, canceling, reducing, or otherwise mitigating) the higher-order-harmonic effects of the primary HEMT with the higher-order-harmonic effects of the complementary HEMT. In other examples, other power switches, such as metal-oxide-semiconductor field-effect transistors (MOSFETs), may be implemented in lieu of, or in addition to, HEMTs.

Examples of the disclosure may be implemented in connection with power amplifiers in many types of electronic devices or systems, such as consumer electronics (for example, televisions, gaming consoles, personal computers, tablet computers, desktop computers, and so forth), vehicles, communication equipment, electrical-utility equipment, or other devices or systems having power amplifiers. For purposes of explanation, examples are provided with reference to wireless devices. For example, the wireless device may include a mobile telephone, such as a smartphone. However, it is to be appreciated that the principles of the disclosure are more broadly applicable to power amplifiers in any of various devices or systems, and that wireless devices are described for purposes of example only.

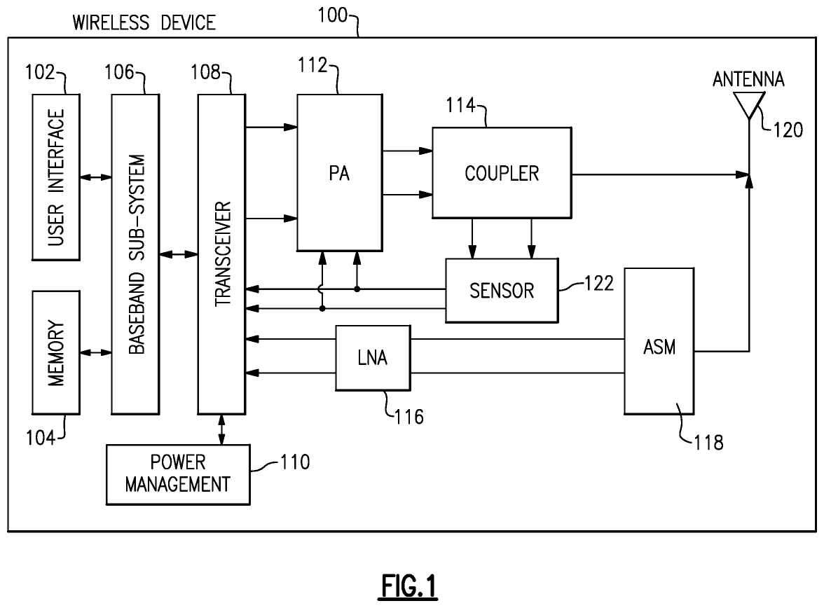

FIG. 1 illustrates a block diagram of a wireless device 100 according to an example. The wireless device 100 can be a cellular phone, smart phone, tablet, modem, communication network or any other portable or non-portable device configured for voice and/or data communication. The wireless device 100 includes a user interface 102, memory and/or storage 104, a baseband sub-system 106, a transceiver 108, a power-management system 110, a power-amplifier (PA) module 112, a coupler 114, a low-noise amplifier (LNA) 116, a switching circuit 118 (also referred to as an antenna switch module [ASM]), an antenna 120, and at least one sensor 122.

The antenna 120 is configured to transmit and/or receive one or more signals, such that the wireless device 100 may communicate with one or more external devices via the antenna 120. The transceiver 108 is configured to generate signals for transmission and/or to process received signals. In some embodiments, transmission and reception functionalities can be implemented in separate components (for example, a transmit module and a receiving module) or be implemented in the same module.

Signals generated for transmission are provided from the transceiver 108 to the PA module 112, which amplifies the generated signals from the transceiver 108. As will be appreciated by those skilled in the art, the PA module 112 can include one or more power amplifiers. The PA module 112 can be used to amplify a wide variety of radio-frequency (RF) or other frequency-band transmission signals. For example, the PA module 112 can receive an enable signal that can be used to pulse the output of the power amplifier to aid in transmitting a wireless local-area-network (WLAN) signal or any other suitable pulsed signal. The PA module 112 can be configured to amplify any of a variety of types of signal, including, for example, a Global System for Mobile (GSM) signal, a code-division multiple-access (CDMA) signal, a W-CDMA signal, a Long-Term-Evolution (LTE) signal, or an EDGE signal. In certain embodiments, the PA module 112 and associated components including switches and the like can be fabricated on GaAs substrates using, for example, pHEMT or BiFET transistors, or on a silicon substrate using CMOS transistors. The wireless device 100 also includes the LNA 116, which may include one or more power amplifiers configured to amplify received signals in a similar or different manner as power amplifier(s) of the PA module 112.

The wireless device 100 also includes the switching circuit 118, which is configured to switch between different bands and/or modes. For example, the switching circuit 118 may be configured to couple the LNA 116 to the antenna 120 in a receive mode of operation and to decouple the LNA 116 from the antenna 120 in a transmit mode of operation. Similarly, the PA module 112 is coupled to the antenna 120 such that signals provided to the antenna 120 from the PA module 112 in the transmit mode of operation bypass the receive path (and switching circuit 118) of the wireless device 100.

Accordingly, in certain embodiments the antenna 120 can both receive signals that are provided to the transceiver 108 via the switching circuit 118 and the LNA 116 and also transmit signals from the wireless device 100 via the transceiver 108, the PA module 112, and the coupler 114. However, in other examples multiple antennas can be used for different modes of operation.

The power-management system 110 is connected to the transceiver 108 and is configured to manage the power for the operation of the wireless device 100. The power-management system 110 can also control the operation of the wireless device 100, such as by controlling components of power amplifier(s) of the PA module 112 and/or LNA 116. The power-management system 110 can include, or can be connected to, a battery that supplies power for the various components of the wireless device 100. The power-management system 110 can further include one or more processors or controllers that can control the transmission of signals and can also configure components of the wireless device 100 based upon the frequency of the signals being transmitted or received, for example. In addition, the processor(s) or controller(s) of the power-management system 110 may provide control signals to actuate switches, tune components, or otherwise configure components of the wireless device 100, such as components of the PA module 112 and/or LNA 116, as discussed below. In at least one embodiment, the processor(s) or controller(s) of the power-management system 110 can also provide control signals to control the switching circuit 118 to operate in the transmit or receive mode.

In one embodiment, the baseband sub-system 106 is connected to the user interface 102 to facilitate various input and output of voice and/or data provided to and received from the user. The baseband sub-system 106 can also be connected to the memory and/or storage 104 which is configured to store data and/or instructions to facilitate the operation of the wireless device, and/or to provide storage of information for the user.

The wireless device 100 also includes the coupler 114 having one or more coupler sections for measuring transmitted power signals from the PA module 112 and for providing one or more coupled signals to at least one sensor 122. In some examples, the coupler 114 is further configured to measure transmitted power signals from the LNA 116. In various examples, the wireless device 100 includes one or more couplers in addition to, or in lieu of, the coupler 114 to measure transmitted power signals from the LNA 116.

The at least one sensor 122 can in turn send information to the transceiver 108, power-management system 110, and/or directly to the PA module 112 and/or LNA 116 as feedback for making adjustments to regulate the power level of the PA module 112 and/or LNA 116. In this way the coupler 114 can be used to boost/decrease the power of a transmission signal having a relatively low/high power. It will be appreciated, however, that the coupler 114 can be used in a variety of other implementations.

For example, in certain embodiments in which the wireless device 100 is a mobile phone having a time division multiple access (TDMA) architecture, the coupler 114 can advantageously manage the amplification of an RF transmitted power signal from the PA module 112 and/or LNA 116. In a mobile phone having a TDMA architecture, such as those found in GSM, CDMA, and W-CDMA systems, the PA module 112 can be used to shift power envelopes up and down within prescribed limits of power versus time. For instance, a particular mobile phone can be assigned a transmission time slot for a particular frequency channel. In this case the PA module 112 and/or LNA 116 can be employed to aid in regulating the power level one or more RF power signals over time, so as to prevent signal interference from transmission during an assigned receive time slot and to reduce power consumption. In such systems, the coupler 114 can be used to measure the power of a power-amplifier output signal to aid in controlling the PA module 112 and/or LNA 116, as discussed above. The implementations shown in FIG. 1 is exemplary and non-limiting. For example, although the implementation of FIG. 1 illustrates the coupler 114 being used in conjunction with a transmission of an RF signal, however, various examples of the coupler 114 discussed herein can also be used with received RF signals or other signals as well.

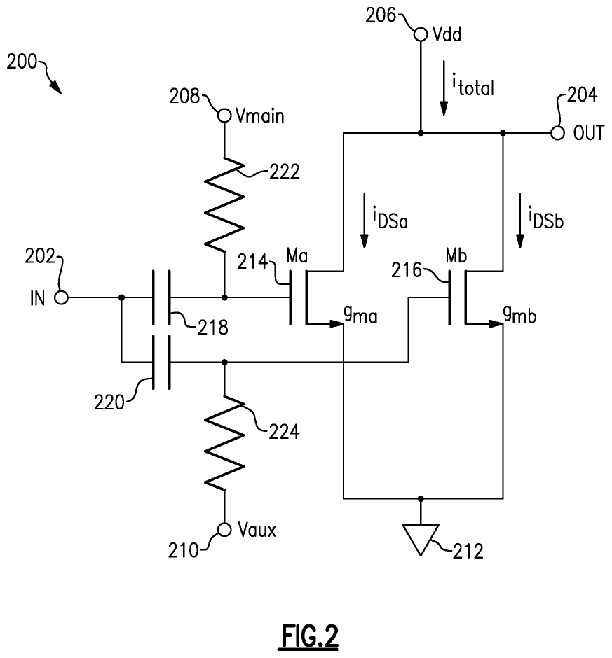

As discussed above, the PA module 112 and/or LNA 116 may each include one or more power amplifiers. FIG. 2 illustrates a schematic diagram of a power amplifier 200 according to an example. For purposes of explanation, examples are provided in which the PA module 112 may include the power amplifier 200, for example, to amplify one or more signals transmitted via the antenna 120. In other examples, the power amplifier 200 may be implemented in connection with one or more other electronic devices, which may or may not be wireless devices, and/or in connection with the LNA 116.

The power amplifier 200 includes an input-signal connection 202, an output-signal connection 204, a drain-voltage (V_{dd}) connection 206, a main-voltage (Vₘₐᵢₙ) connection 208, an auxiliary-voltage (Vₐᵤₓ) connection 210, a reference-voltage connection 212, a primary switch 214, an auxiliary switch 216, a primary capacitor 218, an auxiliary capacitor 220, a primary resistor 222, and an auxiliary resistor 224.

The input-signal connection 202 is coupled to the primary capacitor 218 and the auxiliary capacitor 220, and is configured to be coupled to an input-signal source (not illustrated). The output-signal connection 204 is coupled to the drain-voltage connection 206, the primary switch 214, and the auxiliary switch 216, and is configured to be coupled to a recipient of an output signal (not illustrated), such as the coupler 114 or the antenna 120. The drain-voltage connection 206 is coupled to the output-signal connection 204, the primary switch 214, and the auxiliary switch 216, and is configured to be coupled to a voltage source (for example, a source of a drain voltage V_{dd}) (not illustrated).

The main-voltage connection 208 is coupled to the primary resistor 222, and is configured to be coupled to a first bias-voltage source (for example, a source of a main voltage Vₘₐᵢₙ) (not illustrated). The auxiliary-voltage connection 210 is coupled to the auxiliary resistor 224, and is configured to be coupled to a second bias-voltage source (for example, a source of an auxiliary voltage Vₐᵤₓ) (not illustrated). The reference-voltage connection 212 is coupled to the primary switch 214 and the auxiliary switch 216, and is configured to be coupled to a reference-voltage node (for example, a neutral-voltage node).

In one example, the primary switch 214 is a HEMT having a drain connection coupled to the output-signal connection 204, the drain-voltage connection 206, and the auxiliary switch 216, a source connection coupled to the reference-voltage connection 212, and a gate connection coupled to the primary capacitor 218 and the primary resistor 222. In other examples, the primary switch 214 may be implemented as a switching device other than a HEMT, such as a MOSFET.

In one example, the auxiliary switch 216 is a HEMT having a drain connection coupled to the output-signal connection 204, the drain-voltage connection 206, and the primary switch 214, a source connection coupled to the reference-voltage connection 212, and a gate connection coupled to the auxiliary capacitor 220 and the auxiliary resistor 224. In other examples, the auxiliary switch 216 may be implemented as a switching device other than a HEMT, such as a MOSFET.

The primary capacitor 218 is coupled to the input-signal connection 202 and the auxiliary capacitor 220 at a first connection, and is coupled to the primary resistor 222 and the primary switch 214 at a second connection. The auxiliary capacitor 220 is coupled to the input-signal connection 202 and the primary capacitor 218 at a first connection, and is coupled to the auxiliary resistor 224 and the auxiliary switch 216 at a second connection.

The primary resistor 222 is coupled to the main-voltage connection 208 at a first connection, and is coupled to the primary capacitor 218 and the primary switch 214 at a second connection. The auxiliary resistor 224 is coupled to the auxiliary-voltage connection 210 at a first connection, and is coupled to the auxiliary capacitor 220 and the auxiliary switch 216 at a second connection.

The power amplifier 200 is configured to receive an input signal at the input-signal connection 202, amplify the received signal, and output the amplified signal at the output-signal connection 204. In some examples, the input signal may include an RF signal. A DC component of the input signal may be filtered by the capacitors 218, 220. The filtered signal may be provided to the switches 214, 216 to drive the switches 214, 216. The voltage connections 208, 210 may provide a DC bias voltage to the switches 214, 216, respectively, via the resistors 222, 224, respectively.

In some examples, the switches 214, 216 may be fabricated to be substantially similar or identical devices. However, a bias voltage provided to the primary switch 214 via the main-voltage connection 208 may differ from a bias voltage provided to the auxiliary switch 216 via the auxiliary-voltage connection 210. For example, the primary switch 214 may be biased in the strong-inversion region, whereas the auxiliary switch 216 may be biased in the sub-threshold region. Accordingly, the primary switch 214 may be considered the “primary” amplifying device inasmuch as the primary switch 214 conducts more current than the auxiliary switch 216. The primary switch 214 is therefore primarily responsible for amplifying an input signal.

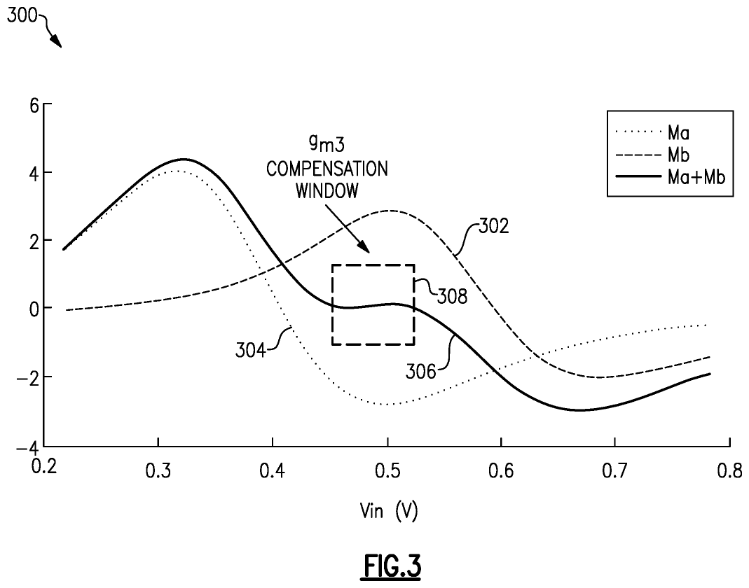

However, the primary switch 214 may not be a perfectly linear device. That is, a gain of the primary switch 214 may vary based on a magnitude of an input signal received at the input-signal connection 202. For example, higher-order harmonics may adversely impact a linearity of the primary switch 214. The auxiliary switch 216 may be implemented to mitigate the higher-order effects. For example, the auxiliary switch 216 may be biased such that higher-order harmonics in the auxiliary switch 216 balance (for example, reduce or cancel) the higher-order harmonics in the primary switch 214. As discussed below with respect to FIG. 3, this process may be referred to as derivative superposition.

FIG. 3 illustrates a graph 300 of third-order harmonics in a transconductance of the power amplifier 200 according to an example. In this example, the switches 214, 216 may be substantially similar or identical although, as discussed above, the switches 214, 216 may be operated differently. An x-axis of the graph 300 indicates a voltage of an input signal (Vᵢₙ) at the input-signal connection 202, and a y-axis of the graph 300 indicates a second derivative of the transconductance of the power amplifier 200. A first trace 302 indicates a second derivative of the transconductance of the primary switch 214 as a function of Vᵢₙ, and a second trace 304 indicates a second derivative of the transconductance of the auxiliary switch 216 as a function of Vᵢₙ. A third trace 306 indicates a sum of the traces 302, 304, which may indicate a second derivative of the transconductance of the power amplifier 200 as a whole.

It may be advantageous for the third trace 306 to be substantially zero. Because the derivative of the transconductance indicates a rate of change of the transconductance, which may be indicative of a rate of change of the gain, the third trace 306 being zero may indicate that the transconductance is not changing, that is, the transconductance (and, for example, the gain) is substantially linear. Therefore, it may be advantageous for the first trace 302 to cancel out the second trace 304 such that the third trace 306 is zero.

The graph 300 includes a region 308 in which the third trace 306 is substantially zero, indicating a range of Vᵢₙ values for which linearity of the power amplifier 200 may be advantageously high. Accordingly, implementing derivative superposition may advantageously mitigate or cancel higher-order harmonics that would otherwise decrease a linearity of the power amplifier 200, at least within certain ranges of Vᵢₙ values. It may be advantageous to align the region 308 around an operating range of Vᵢₙ.

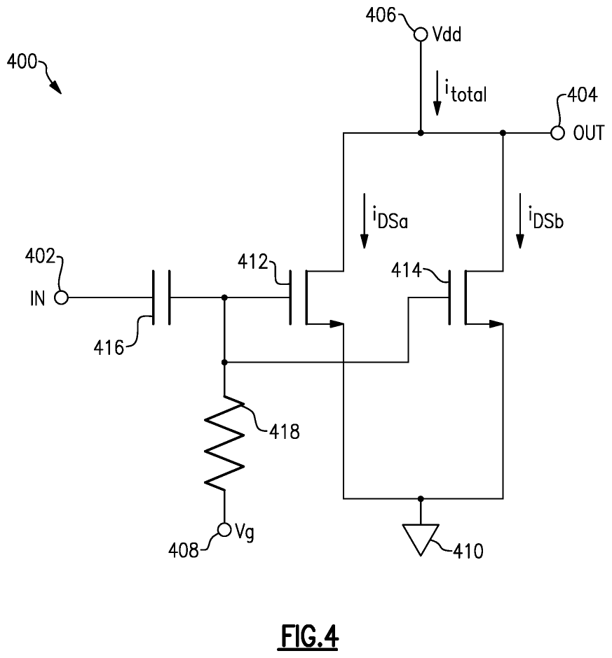

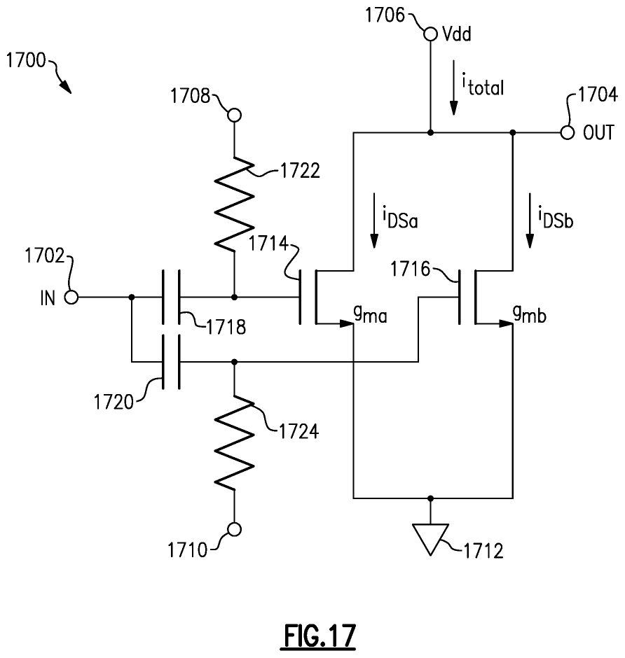

As discussed above, the switches 214, 216 may be fabricated to be substantially similar or identical devices in some examples, although different control signals may be provided to the switches 214, 216. In alternate examples, a power amplifier may include multiple devices implementing derivative superposition in which the devices are not substantially similar or identical devices. For example, a first power-amplifier switch may be a depletion-mode HEMT (or “DFET”), and a second power-amplifier switch may be an enhancement-mode HEMT (or “EFET”). In some examples the power-amplifier switches may be of the same or different sizes. For example, a DFET may be larger than an EFET. In some examples the power-amplifier switches may share a common bias voltage, as discussed with respect to FIG. 4. In other examples, the power-amplifier switches may each have dedicated bias-voltage sources, as discussed with respect to FIG. 17.

FIG. 4 illustrates a schematic diagram of a power amplifier 400 according to an example. The power amplifier 400 is similar to the power amplifier 200. However, as discussed below, the power amplifier 400 includes a single bias-voltage connection. Furthermore, the power amplifier 400 includes a DFET-type switch and an EFET-type switch, whereas the switches 214, 216 of the power amplifier 200 may be substantially similar or identical switches.

The power amplifier 400 includes an input-signal connection 402, an output-signal connection 404, a drain-voltage (V_{dd}) connection 406, a gate-voltage (Vg) connection 408, a reference-voltage connection 410, a primary switch 412, an auxiliary switch 414, a capacitor 416, and a resistor 418.

The input-signal connection 402 is coupled to the capacitor 416, and is configured to be coupled to an input-signal source (not illustrated). The output-signal connection 404 is coupled to the drain-voltage connection 406, the primary switch 412, and the auxiliary switch 414, and is configured to be coupled to a recipient of an output signal (not illustrated), such as the coupler 114 or the antenna 120. The drain-voltage connection 406 is coupled to the output-signal connection 404, the primary switch 412, and the auxiliary switch 414, and is configured to be coupled to a voltage source (for example, a source of a drain voltage V_{dd}) (not illustrated).

The gate-voltage connection 408 is coupled to the resistor 418, and is configured to be coupled to a bias-voltage source (not illustrated). The reference-voltage connection 410 is coupled to the primary switch 412 and the auxiliary switch 414, and is configured to be coupled to a reference-voltage node (for example, a neutral-voltage node).

In one example, the primary switch 412 is a DFET having a drain connection coupled to the output-signal connection 404, the drain-voltage connection 406, and the auxiliary switch 414, a source connection coupled to the reference-voltage connection 410, and a gate connection coupled to the auxiliary switch 414, the capacitor 416, and the resistor 418. Accordingly, the primary switch 412 may be referred to as the “DFET 412.” In other examples, the primary switch 412 may be implemented as a switching device other than a DFET.

In one example, the auxiliary switch 414 is an EFET having a drain connection coupled to the output-signal connection 404, the drain-voltage connection 406, and the primary switch 412, a source connection coupled to the reference-voltage connection 410, and a gate connection coupled to the primary switch 412, the capacitor 416, and the resistor 418. Accordingly, the auxiliary switch 414 may be referred to as the “EFET 414.” In other examples, the auxiliary switch 414 may be implemented as a switching device other than an EFET.

The capacitor 416 is coupled to the input-signal connection 402 at a first connection, and is coupled to the primary switch 412, the auxiliary switch 414, and the resistor 418 at a second connection. The resistor 418 is coupled to the gate-voltage connection 408 at a first connection, and is coupled to the primary switch 412, the auxiliary switch 414, and the capacitor 416 at a second connection.

Similar to the power amplifier 200, the power amplifier 400 is configured to receive an input signal (for example, an RF signal) at the input-signal connection 402, amplify the received signal, and output the amplified signal at the output-signal connection 404. A DC component of the input signal may be filtered by the capacitor 416, and the filtered signal may be provided to the switches 412, 414 to drive the switches 412, 414. The gate-voltage connection 408 may provide a DC bias voltage to the switches 412, 414 via the resistor 418.

In some examples, higher-order harmonics in the switches 412, 414 may cancel one another out as a result of the switches 412, 414 being of different types. For example, at a given gate voltage applied to the switches 412, 414, a third-order harmonic for the DFET 412 may be negative whereas a third-order harmonic for the EFET 414 may be positive. As discussed above with respect to the graph 300, the third-order harmonics may at least partially cancel one another out.

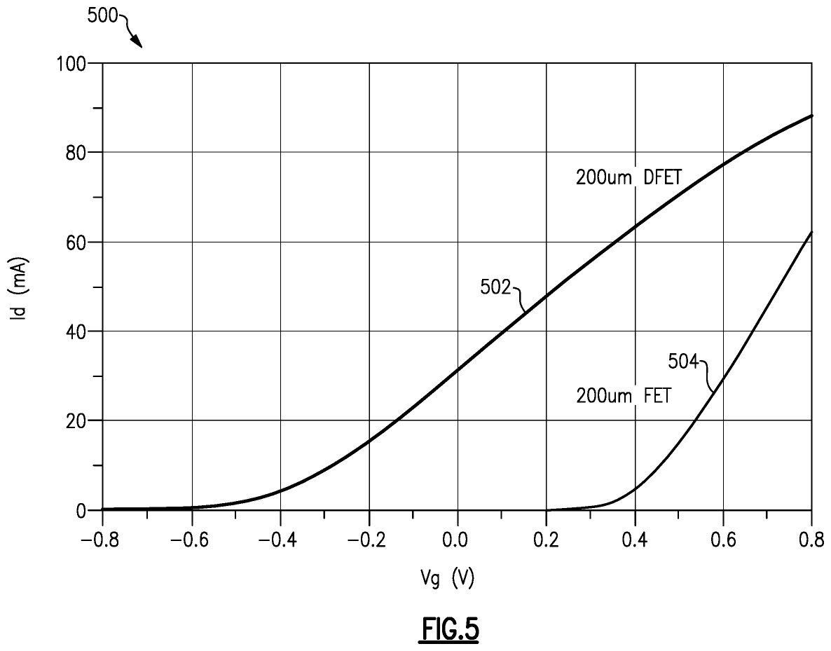

In some examples, however, a magnitude of the harmonics may differ for an EFET and an identically sized DFET. For example, at a given gate voltage, a magnitude of a positive third-order harmonic in the EFET 414 may be substantially larger than a magnitude of a negative third-order harmonic in the DFET 412. Thus, while the third-order harmonics may counteract each other, the sum of the third-order harmonics may “overshoot” zero and still have a large magnitude. These principles are discussed below with respect to FIGS. 5-8, which illustrate properties of an EFET and an identically sized DFET.

FIG. 5 illustrates a graph 500 of switch drain currents as a function of gate voltage according to an example. An x-axis indicates a gate voltage (Vg) applied to a gate of a switch, and a y-axis indicates a drain current (Id) conducted by the switch. A first trace 502 indicates a drain current as a function of gate voltage for a DFET, and a second trace 504 indicates a drain current as a function of gate voltage for an identically sized EFET (for example, 200 microns).

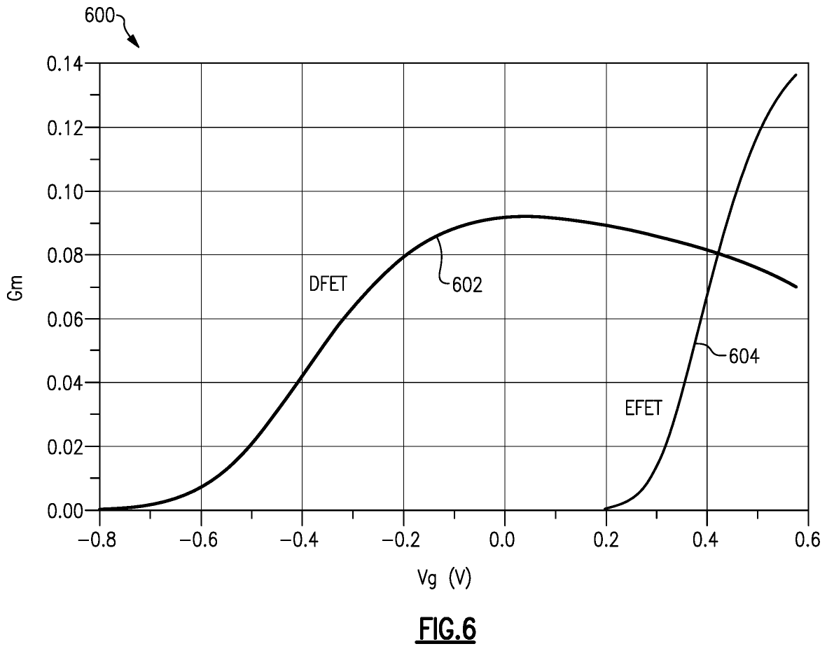

FIG. 6 illustrates a graph 600 of respective switch transconductances as a function of gate voltage according to an example. An x-axis indicates a gate voltage (Vg) applied to a gate of a switch, and a y-axis indicates a transconductance (Gm) of the switch. The transconductance of the switch may be equal to a derivative of the switch current as a function of gate voltage, that is, a slope of the traces 502, 504. A first trace 602 indicates a transconductance as a function of gate voltage for a DFET, and a second trace 604 indicates a transconductance as a function of gate voltage for an identically sized EFET.

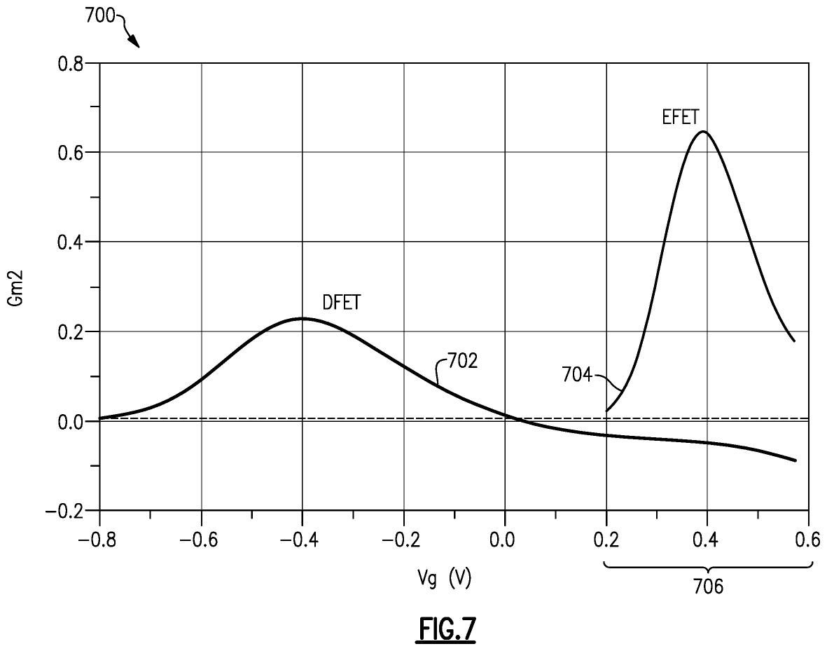

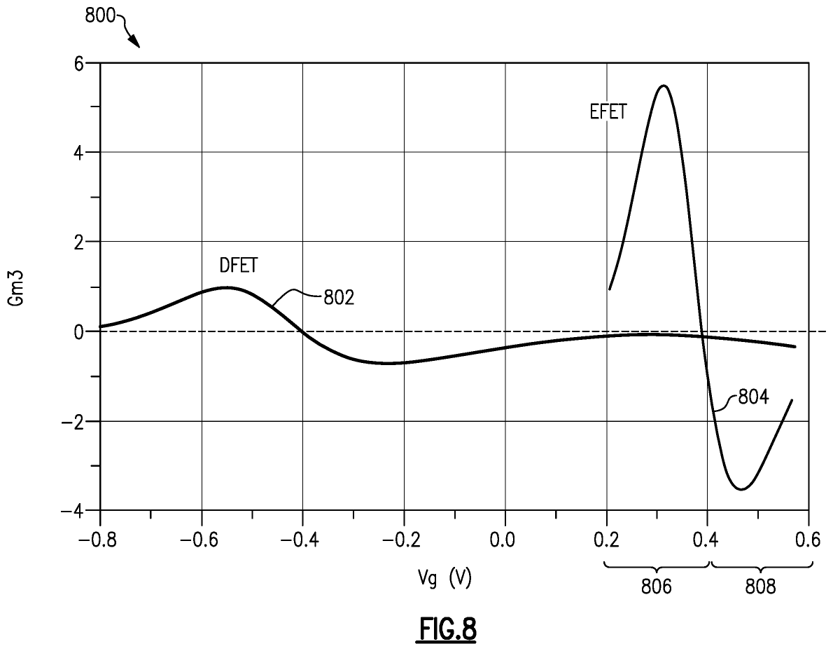

As indicated by the traces 602, 604, the transconductances of the DFET and EFET may vary as a function of gate voltage (that is, the transconductances are non-linear). This non-linearity may be due to higher-order harmonics. These higher-order harmonics may include second- and third-order harmonics. Second-order harmonics may be analyzed by taking a first derivative of the traces 602, 604, as illustrated and discussed below in FIG. 7. Third-order harmonics may be analyzed by taking a second derivative of the traces 602, 604, as illustrated and discussed below in FIG. 8.

FIG. 7 illustrates a graph 700 of switch second-order harmonics as a function of gate voltage according to an example. An x-axis indicates a gate voltage (Vg) applied to a gate of a switch, and a y-axis indicates a derivative (Gm2) of the transconductance (Gm) of the switch. The derivative of the transconductance of the switch may be equal to a second derivative of the switch current as a function of gate voltage, that is, a slope of the traces 602, 604. A first trace 702 indicates a derivative of the transconductance of a DFET as a function of gate voltage, and a second trace 704 indicates a derivative of the transconductance of an identically sized EFET as a function of gate voltage.

It may be advantageous for a sum of the traces 702, 704 to be approximately zero to improve linearity of a power amplifier including the DFET and EFET. In this manner, the second-order harmonics of the DFET and EFET may cancel one another such that an overall power-amplifier linearity is improved.

For example, in a first range of gate-voltage values 706, a value of the first trace 702 is negative (indicating a decreasing transconductance value of the DFET), and a value of the second trace 704 is positive (indicating an increasing transconductance value of the EFET). Therefore, at gate voltages within the first range of gate-voltage values 706, the second-order harmonics in the EFET may counteract those in the DFET. However, because the magnitudes of the traces 702, 704 are not equal, the sum may not be zero, indicating that second-order harmonics remain. As discussed below, this may be addressed by varying the sizes of the DFET and/or the EFET.

Similarly, FIG. 8 illustrates a graph 800 of switch third-order harmonics as a function of gate voltage according to an example. An x-axis indicates a gate voltage (Vg) applied to a gate of a switch, and a y-axis indicates a second derivative (Gm3) of the transconductance (Gm) of the switch. The second derivative of the transconductance of the switch may be equal to a third derivative of the switch current as a function of gate voltage, that is, a slope of the traces 702, 704. A first trace 802 indicates a second derivative of the transconductance of the DFET as a function of gate voltage, and a second trace 804 indicates a second derivative of the transconductance of the EFET as a function of gate voltage.

In a second range of gate-voltage values 806, a value of the first trace 802 is negative, and a value of the second trace 804 is positive. Therefore, at gate voltages within the second range of gate-voltage values 806, the third-order harmonics in the EFET may counteract those in the DFET. By contrast, in a third range of gate-voltage values 808, a value of both of the traces 802, 804 is negative. Therefore, at gate voltages within the third range of gate-voltage values 808, the third-order harmonics in the EFET may add to those in the DFET.

However, even for gate voltages within the second range of gate-voltage values 806, the magnitudes of the traces 802, 804 are not equal. Accordingly, a sum of the traces 802, 804 is not zero, indicating that third-order harmonics remain. As discussed below, this may be addressed by varying the sizes of the DFET and EFET.

Accordingly, for gate-bias voltages between approximately 0.2V and 0.4V (that is, gate-bias voltages within both the first range of gate-voltage values 706 and the second range of gate-voltage values 806), second- and third-order harmonics of the EFET 414 may counteract those of the DFET 412. However, if the switches 412, 414 are identically sized, the EFET 414 may overcorrect the harmonics of the DFET 412, because—as illustrated in FIGS. 7 and 8—a magnitude of the second- and third-order harmonics in the EFET 414 may be substantially larger than a magnitude of the second- and third-order harmonics in the DFET 412.

It may be advantageous to reduce a size of the EFET 414 relative to the DFET 412 such that the respective magnitudes of the second- and third-order harmonics in the EFET 414 are reduced. In one example, the DFET 412 may have a size of approximately 4×50 microns, and the EFET 414 may have a size of approximately 1×11 microns. By reducing a size of the EFET 414 relative to the DFET 412, the EFET 414 may further balance the DFET 412 such that a linearity of the power amplifier 400 is improved.

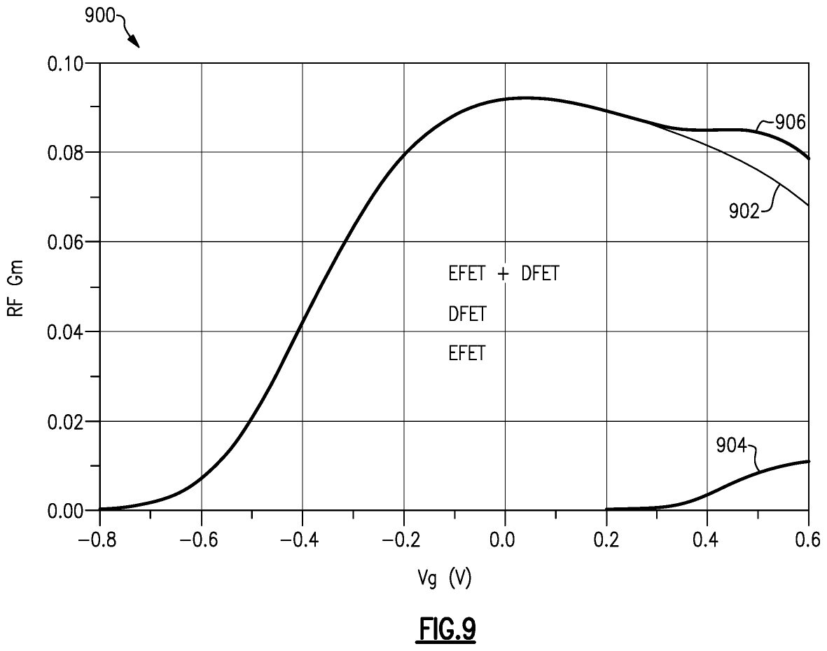

For example, FIG. 9 illustrates a graph 900 of respective switch transconductances as a function of gate voltage according to an example. In this example, the EFET 414 may be smaller than the DFET 412. An x-axis indicates a gate voltage (Vg) applied to a gate of a switch, and a y-axis indicates a transconductance (Gm) of the switch.

A first trace 902 indicates a transconductance as a function of gate voltage for the DFET 412. A second trace 904 indicates a transconductance as a function of gate voltage for the EFET 414. A third trace 906 indicates a transconductance as a function of gate voltage for the power amplifier 400 including both the DFET 412 and the EFET 414. Comparing the second trace 904 to the second trace 604, it can be seen that reducing a size of the EFET 414 similarly reduces a transconductance of the EFET 414 to a magnitude that is better-suited to balancing the transconductance of the DFET 412.

As indicated by the traces 902, 906, the transconductance of the power amplifier 400 is significantly more linear than the transconductance of the DFET 412 alone where the EFET 414 is conductive (that is, above a turn-on voltage of the EFET 414). Accordingly, a linearity of the power amplifier 400 is improved by including the EFET 414 and sizing the EFET 414 to balance the transconductance of the DFET 412.

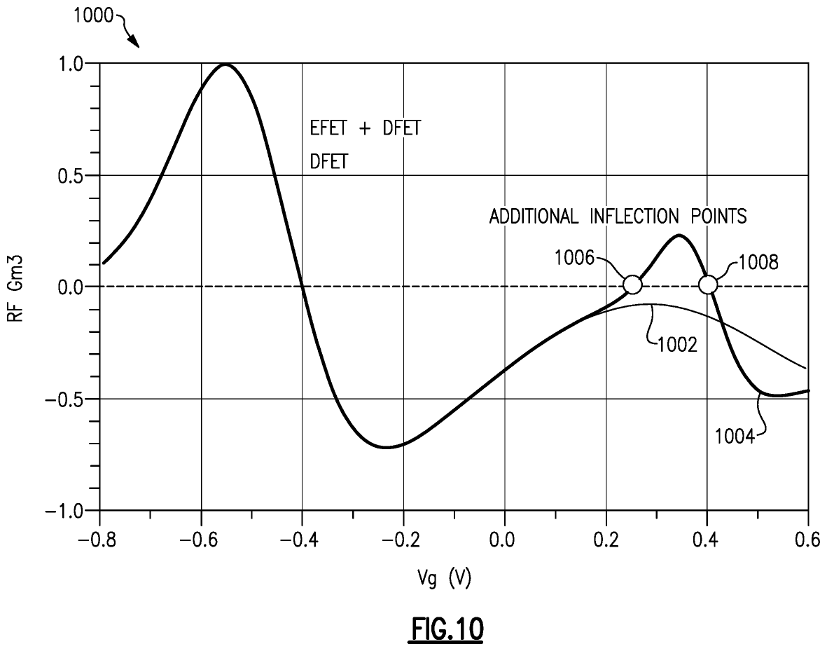

Analyzing higher-order harmonics of the switches 412, 414 may facilitate the identification of gate-voltage values at which the higher-order harmonics may be canceled. FIG. 10 illustrates a graph 1000 of switch third-order harmonics as a function of gate voltage according to an example. An x-axis indicates a gate voltage (Vg) applied to a gate of a switch, and a y-axis indicates a second derivative (Gm3) of the transconductance (Gm) of the switch.

A first trace 1002 indicates a second derivative of the transconductance of the DFET 412 in isolation (that is, without the EFET 414) as a function of gate voltage. A second trace 1004 indicates a second derivative of the transconductance of the power amplifier 400 including both the DFET 412 and the EFET 414 as a function of gate voltage. At positive gate-voltage values, third-order harmonics are always present in the DFET 412 (that is, a value of the first trace 1002 is never zero). Conversely, third-order harmonics are entirely canceled in the power amplifier 400 at a first gate-voltage value 1006 and a second gate-voltage value 1008. In some examples, it may be advantageous to provide a gate-voltage value equal to either of the values 1006, 1008 at the gate-voltage connection 408 such that third-order harmonics in the DFET 412 are eliminated or mitigated by the EFET 414. Accordingly, implementing the EFET 414 in an appropriate size may advantageously improve a linearity of the power amplifier 400.

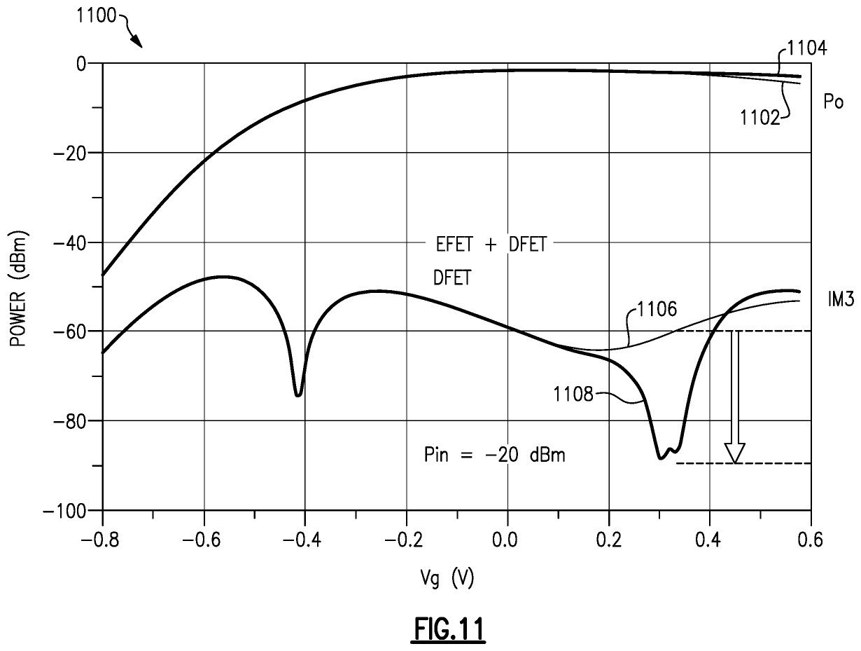

FIG. 11 illustrates a graph 1100 of an output power (Po) and a third-order intermodulation point (IM3) as a function of gate voltage at a constant input power (Pin) according to an example. A first trace 1102 indicates an output power of the DFET 412 in isolation (that is, without the EFET 414). A second trace 1104 indicates an output power of the power amplifier 400 including both the DFET 412 and the EFET 414. A third trace 1106 indicates a third-order intermodulation point of the DFET 412 in isolation (that is, without the EFET 414). A fourth trace 1108 indicates a third-order intermodulation point of the power amplifier 400 including both the DFET 412 and the EFET 414.

As indicated by the traces 1102, 1104, an output power of the power amplifier 400 remains relatively unaffected by the EFET 414. As indicated by the traces 1106, 1108, a third-order intermodulation point of the power amplifier 400 is advantageously reduced by the EFET 414 across a wide range of gate-voltage values (for example, between approximately 0.18V and 0.42V).

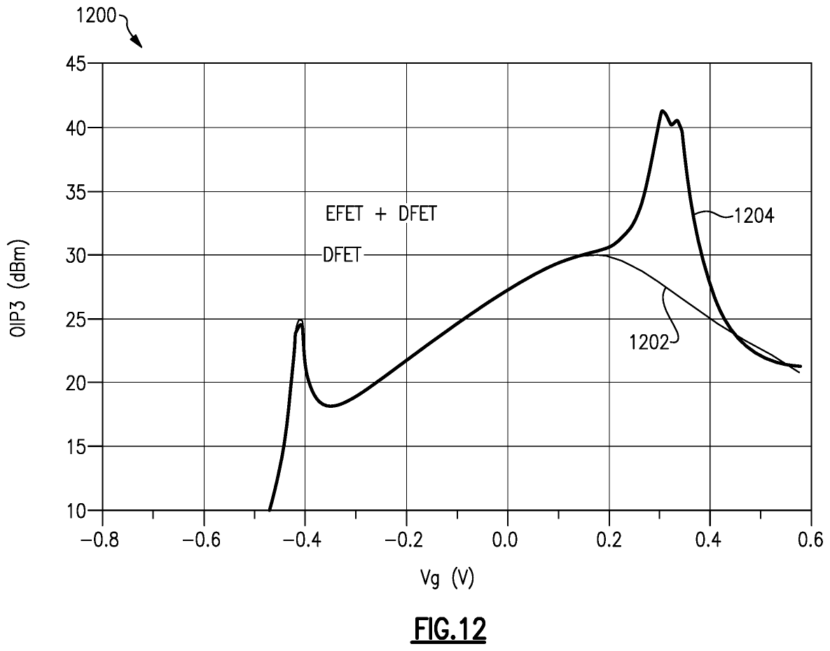

FIG. 12 illustrates a graph 1200 of a third-order output intercept point (OIP3) as a function of gate voltage (Vg) according to an example. A first trace 1202 indicates a third-order output intercept point of the DFET 412 in isolation (that is, without the EFET 414). A second trace 1204 indicates a third-order output intercept point of the power amplifier 400 including both the DFET 412 and the EFET 414. As indicated by the traces 1202, 1204, a third-order output intercept point of the power amplifier 400 is advantageously increased by the EFET 414 across a wide range of gate-voltage values (for example, between approximately 0.18V and approximately 0.42V).

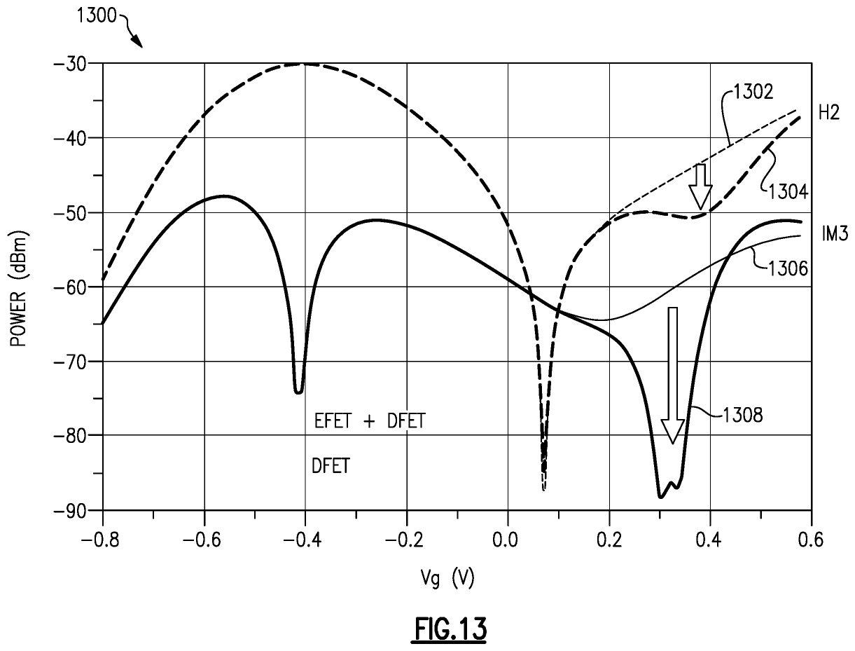

FIG. 13 illustrates a graph 1300 of second-order harmonics (H2) and a third-order intermodulation point (IM3) as a function of gate voltage according to an example. A first trace 1302 indicates second-order harmonics of the DFET 412 in isolation (that is, without the EFET 414). A second trace 1304 indicates second-order harmonics of the power amplifier 400 including both the DFET 412 and the EFET 414. A third trace 1306 indicates a third-order intermodulation point of the DFET 412 in isolation (that is, without the EFET 414). A fourth trace 1308 indicates a third-order intermodulation point of the power amplifier 400 including both the DFET 412 and the EFET 414.

As indicated by the traces 1302, 1304, the EFET 414 may advantageously reduce the effects of second-order harmonics in the power amplifier 400. Moreover, this reduction in second-order harmonics occurs in a substantially overlapping range of gate-voltage values as the reduction in third-order harmonics, as indicated by the traces 1306, 1308. Accordingly, a gate-voltage value may be selected within this range of values to minimize both second- and third-order harmonics.

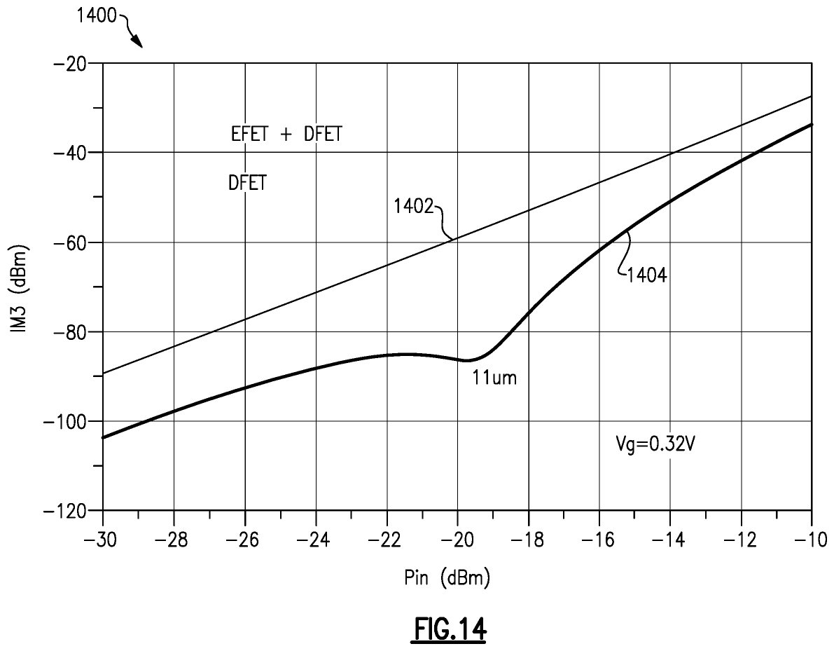

FIG. 14 illustrates a graph 1400 of a third-order intermodulation point (IM3) as a function of input power (Pin) at a constant gate-voltage value according to an example. A first trace 1402 indicates a third-order intermodulation point of the DFET 412 in isolation (that is, without the EFET 414), and a second trace 1404 indicates a third-order intermodulation point of the power amplifier 400 including both the DFET 412 and EFET 414. As indicated by the traces 1402, 1404, the EFET 414 may advantageously reduce a third-order intermodulation point of the power amplifier 400 across a wide range of input-power values. Furthermore, a size of the EFET 414 may be varied to achieve a desired third-order-intermodulation-point value for a given input-power value.

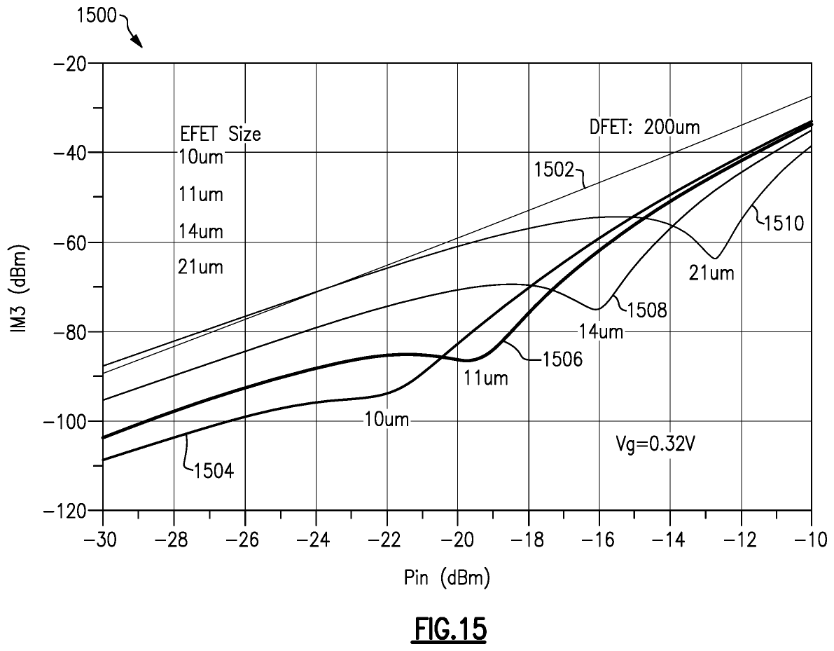

FIG. 15 illustrates a graph 1500 of a third-order intermodulation point (IM3) as a function of input power (Pin) at a constant gate-voltage value and for various sizes of the EFET 414 according to an example. A first trace 1502 indicates a third-order intermodulation point of the DFET 412 in isolation (that is, without the EFET 414). A second trace 1504 indicates a third-order intermodulation point of the power amplifier 400 including both the DFET 412 and EFET 414 in which the EFET 414 has a first size (for example, approximately 10 microns).

A third trace 1506 indicates a third-order intermodulation point of the power amplifier 400 including both the DFET 412 and EFET 414 in which the EFET 414 has a second size (for example, approximately 11 microns). A fourth trace 1508 indicates a third-order intermodulation point of the power amplifier 400 including both the DFET 412 and EFET 414 in which the EFET 414 has a third size (for example, approximately 14 microns). A fifth trace 1510 indicates a third-order intermodulation point of the power amplifier 400 including both the DFET 412 and EFET 414 in which the EFET 414 has a fourth size (for example, approximately 21 microns).

As indicated by the traces 1502-1510, a third-order intermodulation point of the power amplifier 400 may be reduced by including the EFET 414 at a wide range of sizes and input-power values. However, certain sizes of the EFET 414 may be more advantageous than others at certain operating conditions. For example, at an input-power value of approximately −22 dBm, the second trace 1504 indicates a lowest third-order intermodulation point, and it may be desirable to size the EFET 414 at the first size. Conversely, at an input-power value of approximately −12 dBm, the fifth trace 1510 indicates a lowest third-order intermodulation point, and it may be desirable to size the EFET 414 at the fourth size.

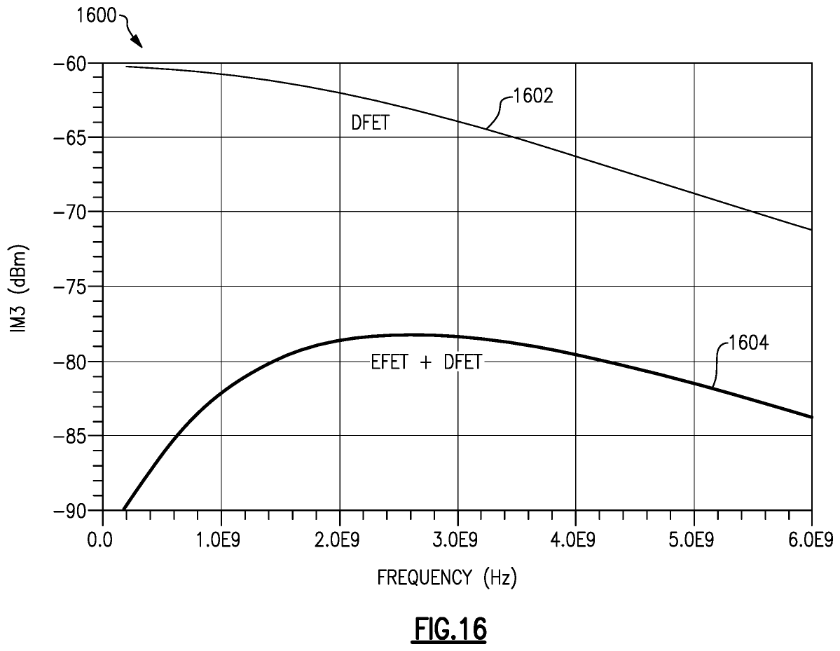

FIG. 16 illustrates a graph 1600 of a third-order intermodulation point (IM3) as a function of input-signal frequency (Hz) at a constant gate-voltage value and input-power value according to an example. A first trace 1602 indicates a third-order intermodulation point of the DFET 412 in isolation (that is, without the EFET 414), and a second trace 1604 indicates a third-order intermodulation point of the power amplifier 400 including both the DFET 412 and EFET 414. As indicated by the traces 1602, 1604, including the EFET 414 advantageously reduces a third-order intermodulation point of the power amplifier 400 across a wide range of input-signal frequencies.

In light of the foregoing, the linearity of a power amplifier including a power switch, such as the power amplifier 400 including the DFET 412, may be improved by adding an auxiliary power switch, such as the EFET 414. For example, the EFET 414 may be selected and sized such that higher-order harmonics in the EFET 414 mitigate or reduce higher-order harmonics in the DFET 412 under the operating conditions at which the power amplifier 400 may operate.

Various modifications are within the scope of the disclosure. For example, although power-amplifier switches may share a common bias-voltage source in some examples, in other examples the power-amplifier switches may each be coupled to a respective bias-voltage source.

FIG. 17 illustrates a schematic diagram of a power amplifier 1700 according to an example. The power amplifier 1700 may be similar to the power amplifier 400, but may include multiple independent bias-voltage sources.

The power amplifier 1700 includes an input-signal connection 1702, an output-signal connection 1704, a drain-voltage (V_{dd}) connection 1706, a DFET-bias-voltage connection 1708, an EFET-bias-voltage connection 1710, a reference-voltage connection 1712, a DFET 1714, an EFET 1716, a primary capacitor 1718, an auxiliary capacitor 1720, a primary resistor 1722, and an auxiliary resistor 1724.

The input-signal connection 1702 is coupled to the primary capacitor 1718 and the auxiliary capacitor 1720, and is configured to be coupled to an input-signal source (not illustrated). The output-signal connection 1704 is coupled to the drain-voltage connection 1706, the DFET 1714, and the EFET 1716, and is configured to be coupled to a recipient of an output signal (not illustrated), such as the coupler 114 or the antenna 120. The drain-voltage connection 1706 is coupled to the output-signal connection 1704, the DFET 1714, and the EFET 1716, and is configured to be coupled to a voltage source (for example, a source of a drain voltage V_{dd}) (not illustrated).

The DFET-bias-voltage connection 1708 is coupled to the primary resistor 1722, and is configured to be coupled to a first bias-voltage source (not illustrated). The EFET-bias-voltage connection 1710 is coupled to the auxiliary resistor 1724, and is configured to be coupled to a second bias-voltage source (not illustrated). The reference-voltage connection 1712 is coupled to the DFET 1714 and the EFET 1716, and is configured to be coupled to a reference-voltage node (for example, a neutral-voltage node).

The DFET 1714 includes a drain connection coupled to the output-signal connection 1704, the drain-voltage connection 1706, and the EFET 1716, a source connection coupled to the reference-voltage connection 1712, and a gate connection coupled to the primary capacitor 1718 and the primary resistor 1722. The EFET 1716 includes a drain connection coupled to the output-signal connection 1704, the drain-voltage connection 1706, and the DFET 1714, a source connection coupled to the reference-voltage connection 1712, and a gate connection coupled to the auxiliary capacitor 1720 and the auxiliary resistor 1724.

The primary capacitor 1718 is coupled to the input-signal connection 1702 and the auxiliary capacitor 1720 at a first connection, and is coupled to the primary resistor 1722 and the DFET 1714 at a second connection. The auxiliary capacitor 1720 is coupled to the input-signal connection 1702 and the primary capacitor 1718 at a first connection, and is coupled to the auxiliary resistor 1724 and the EFET 1716 at a second connection.

The primary resistor 1722 is coupled to the DFET-bias-voltage connection 1708 at a first connection, and is coupled to the primary capacitor 1718 and the DFET 1714 at a second connection. The auxiliary resistor 1724 is coupled to the EFET-bias-voltage connection 1710 at a first connection, and is coupled to the auxiliary capacitor 1720 and the EFET 1716 at a second connection.

The power amplifier 1700 is substantially similar to the power amplifier 400. However, the switches 412, 414 both receive a bias voltage from the gate-voltage connection 408 in the power amplifier 400. In the power amplifier 1700, the DFET 1714 receives a bias voltage from the DFET-bias-voltage connection 1708, and the EFET 1716 receives a bias voltage from the EFET-bias-voltage connection 1710. Accordingly, a bias voltage of the DFET 1714 may be controlled independently from a bias voltage of the EFET 1716. Whereas a bias voltage of the DFET 1714 may be constrained by operating requirements, a size and a bias voltage of the EFET 1716 may be independently selected to optimize a linearity of the power amplifier 1700.

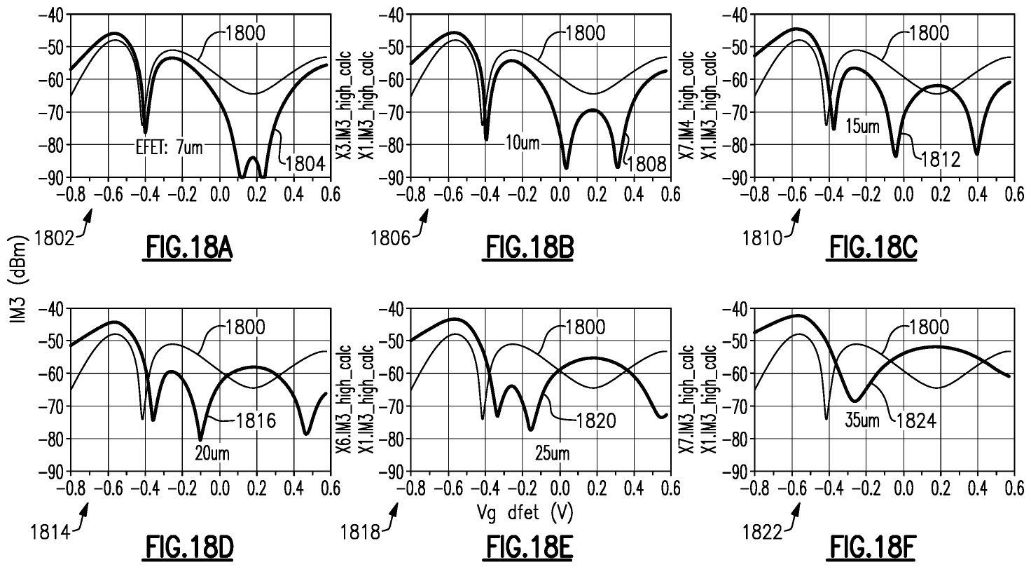

FIGS. 18A-18F illustrate graphs of a third-order intermodulation point (IM3) of the power amplifier 1700 as a function of a bias voltage provided to the DFET 1714 at the DFET-bias-voltage connection 1708 (Vg_dfet) for a constant EFET 1716 bias voltage (for example, 0.34V) and a constant size of the DFET 1714 (for example, 200 microns). In each of the graphs, a first trace 1800 indicates a third-order intermodulation point of the DFET 1714 in isolation (that is, without the EFET 1716) as a function of the DFET 1714 bias voltage.

FIG. 18A illustrates a first graph 1802 of a third-order intermodulation point (IM3) as a function of a gate voltage provided to the DFET 1714 according to an example. The first graph 1802 includes the first trace 1800 and a second trace 1804, which illustrates a third-order intermodulation point of the power amplifier 1700 including both the DFET 1714 and EFET 1716 as a function of the DFET 1714 bias voltage for a first size (for example, approximately 7 microns) of the EFET 1716.

FIG. 18B illustrates a second graph 1806 of a third-order intermodulation point (IM3) as a function of a gate voltage provided to the DFET 1714 according to an example. The second graph 1806 includes the first trace 1800 and a third trace 1808, which illustrates a third-order intermodulation point of the power amplifier 1700 including both the DFET 1714 and EFET 1716 as a function of the DFET 1714 bias voltage for a second size (for example, approximately 10 microns) of the EFET 1716.

FIG. 18C illustrates a third graph 1810 of a third-order intermodulation point (IM3) as a function of a gate voltage provided to the DFET 1714 according to an example. The third graph 1810 includes the first trace 1800 and a fourth trace 1812, which illustrates a third-order intermodulation point of the power amplifier 1700 including both the DFET 1714 and EFET 1716 as a function of the DFET 1714 bias voltage for a third size (for example, approximately 15 microns) of the EFET 1716.

FIG. 18D illustrates a fourth graph 1814 of a third-order intermodulation point (IM3) as a function of a gate voltage provided to the DFET 1714 according to an example. The fourth graph 1814 includes the first trace 1800 and a fifth trace 1816, which illustrates a third-order intermodulation point of the power amplifier 1700 including both the DFET 1714 and EFET 1716 as a function of the DFET 1714 bias voltage for a fourth size (for example, approximately 20 microns) of the EFET 1716.

FIG. 18E illustrates a fifth graph 1818 of a third-order intermodulation point (IM3) as a function of a gate voltage provided to the DFET 1714 according to an example. The fifth graph 1818 includes the first trace 1800 and a sixth trace 1820, which illustrates a third-order intermodulation point of the power amplifier 1700 including both the DFET 1714 and EFET 1716 as a function of the DFET 1714 bias voltage for a fifth size (for example, approximately 25 microns) of the EFET 1716.

FIG. 18F illustrates a sixth graph 1822 of a third-order intermodulation point (IM3) as a function of a gate voltage provided to the DFET 1714 according to an example. The sixth graph 1822 includes the first trace 1800 and a seventh trace 1824, which illustrates a third-order intermodulation point of the power amplifier 1700 including both the DFET 1714 and EFET 1716 as a function of the DFET 1714 bias voltage for a sixth size (for example, approximately 35 microns) of the EFET 1716.

As illustrated in FIGS. 18A-18F, a third-order intermodulation point of the power amplifier 1700 may vary based on a size of the EFET 1716. Accordingly, for a given bias voltage provided the DFET 1714, a size of the EFET 1716 may be selected based on a desired third-order intermodulation point of the power amplifier 1700. Conversely, the bias voltage provided to the EFET 1716 may be maintained at a desired value (for example, approximately 0.34V) independently of the bias voltage provided to the DFET 1714.

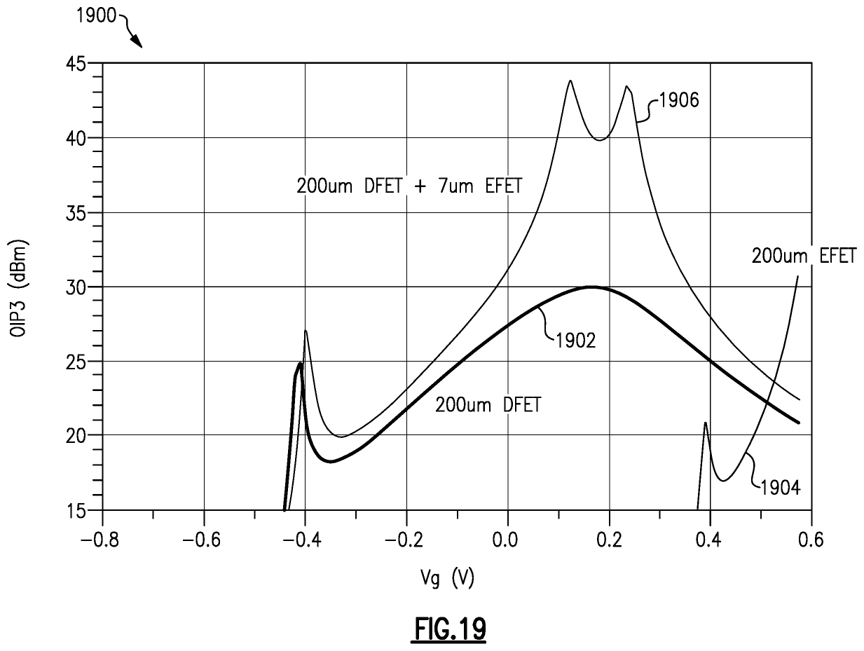

FIG. 19 illustrates a graph 1900 of a third-order output intercept point (OIP3) as a function of gate voltage (Vg) according to an example. For example, the gate voltage may be a bias voltage provided to the DFET 1714. Conversely, a bias voltage provided to the EFET 1716 may be substantially constant (for example, at approximately 0.34V) as the bias voltage provided to the DFET 1714 varies.

A first trace 1902 indicates a third-order output intercept point of the DFET 1714 at a first size (for example, approximately 200 microns) in isolation (that is, without the EFET 1716). A second trace 1904 indicates a third-order output intercept point of the EFET 1716 at a second size (for example, approximately 200 microns) in isolation (that is, without the DFET 1714). A third trace 1906 indicates a third-order output intercept point of the power amplifier 1700 including both the DFET 1714 at the first size and the EFET 1716 at a third size (for example, approximately 7 microns).

As indicated by the traces 1902-1906, a third-order output intercept point of the power amplifier 1700 is advantageously increased by the EFET 1716 across a wide range of DFET-bias-voltage values (for example, between approximately −0.4V and 0.6V), including DFET-bias-voltage values that, if used to bias the EFET 1716, would be below a turn-on voltage of the EFET 1716 (for example, between approximately −0.4V and 0.2V). Accordingly, by providing separate bias voltages to the DFET 1714 and the EFET 1716, the EFET 1716 may increase a third-order output intercept point of the power amplifier 1700 across a wider range of bias voltages provided to the DFET 1714.

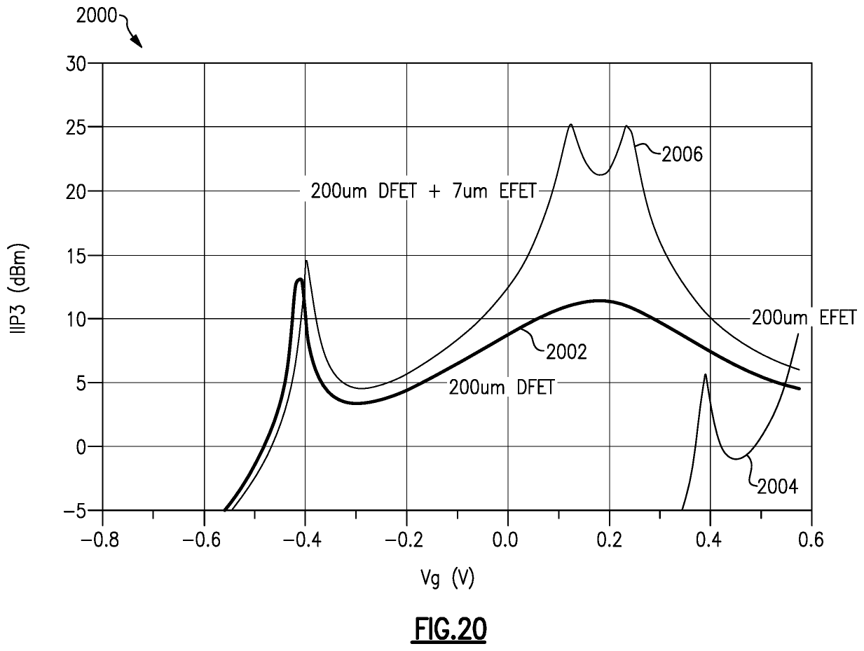

FIG. 20 illustrates a graph 2000 of a third-order input intercept point (IIP3) as a function of gate voltage (Vg) according to an example. For example, the gate voltage may be a bias voltage provided to the DFET 1714. Conversely, a bias voltage provided to the EFET 1716 may be substantially constant (for example, at approximately 0.34V) as the bias voltage provided to the DFET 1714 varies.

A first trace 2002 indicates a third-order input intercept point of the DFET 1714 at a first size (for example, approximately 200 microns) in isolation (that is, without the EFET 1716). A second trace 2004 indicates a third-order input intercept point of the EFET 1716 at a second size (for example, approximately 200 microns) in isolation (that is, without the DFET 1714). A third trace 2006 indicates a third-order input intercept point of the power amplifier 1700 including both the DFET 1714 at the first size and the EFET 1716 at a third size (for example, approximately 7 microns).

As indicated by the traces 2002-2006, a third-order input intercept point of the power amplifier 1700 is advantageously increased by the EFET 1716 across a wide range of DFET-bias-voltage values, including DFET-bias-voltage values that, if used to bias the EFET 1716, would be below a turn-on voltage of the EFET 1716. Accordingly, by providing separate bias voltages to the DFET 1714 and the EFET 1716, the EFET 1716 may increase a third-order input intercept point of the power amplifier 1700 across a wider range of bias voltages provided to the DFET 1714.

In light of the foregoing, a linearity of a power amplifier may be advantageously increased across a wide range of bias-voltage values, input-power values, and input-signal frequencies. An auxiliary power switch may be coupled to a primary power switch. The auxiliary power switch may be designed to offset higher-order harmonics in the primary power switch (including, for example, second- and third-order harmonics), thereby increasing a linearity of the power amplifier. In one example, the primary power switch is a DFET, and the auxiliary power switch is an EFET.

A size of the DFET may differ from (for example, be larger than) a size of the EFET. In some examples, a size of the EFET may be selected based on a size of the DFET. For example, a size of the EFET and/or a size of the DFET may be selected to optimize the linearity of the power amplifier.

In one example, the same bias voltage may be provided to both the DFET and the EFET. In another example, different bias voltages may be provided to the DFET and the EFET. For example, a bias voltage may be provided to the DFET based on operating requirements of the power amplifier, and a bias voltage may be provided to the EFET to increase a linearity of the power amplifier. This may enable an optimal third-order intermodulation point to be achieved for any given DFET bias-voltage value.

In alternate examples, more than two switches may be implemented. Additional switches may be added in parallel and/or in series with the primary and auxiliary switches discussed above. Additional switches may be of the same or a different type than the primary and auxiliary switches. Additional switches may be of the same or different sizes than the primary and auxiliary switches. Additional switches may receive bias voltages from shared or independent bias-voltage sources. Additional switches may be driven by an input signal in some examples, and may be driven by other signals in other examples.

Although the primary and auxiliary switches may be HEMTs in some examples, in other examples, other types of switches may be implemented, such as bipolar-junction transistors, MOSFETs, and so forth. Furthermore, although in some examples a primary switch may be a DFET and an auxiliary switch may be an EFET, in other examples either or both of the switches may be of different types.

Although certain examples of device sizes, power values, frequency values, voltage values, and so forth are provided for purposes of explanation, these examples are not intended to be limiting. Device and/or system properties may vary based on various design requirements. Furthermore, in some examples, a plurality of smaller or larger devices may be implemented in lieu of a single device, although the plurality of devices may exhibit the same system-level properties as the single device.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A power amplifier comprising:
a first power switch of a first type being configured to receive an input signal and provide an amplified output signal to an output connection configured to be coupled to a load; and
a second power switch of a second type different than the first type, the second power switch being configured to improve a linearity of the power amplifier and being coupled to the output connection.

2. The power amplifier of claim 1 wherein the first power switch and the second power switch are high-electron-mobility transistors (HEMTs).

3. The power amplifier of claim 2 wherein the first type is a depletion-type HEMT and the second type is an enhancement-type HEMT.

4. The power amplifier of claim 3 wherein the first power switch is larger than the second power switch.

5. The power amplifier of claim 4 wherein the first power switch is approximately 50 microns and the second power switch is approximately 11 microns.

6. The power amplifier of claim 1 further comprising at least one bias-voltage connection to receive at least one bias voltage and provide the at least one bias voltage to the first power switch and the second power switch.

7. The power amplifier of claim 6 wherein the second power switch is configured to improve the linearity of the power amplifier at the at least one bias voltage.

8. The power amplifier of claim 7 wherein improving the linearity of the power amplifier includes reducing at least one of second-order or third-order harmonics in the first power switch.

9. The power amplifier of claim 6 wherein the at least one bias-voltage connection includes a single bias-voltage connection coupled to the first power switch and the second power switch.

10. The power amplifier of claim 6 wherein the at least one bias-voltage connection includes a first bias-voltage connection coupled to the first power switch and a second bias-voltage connection coupled to the second power switch.

11. The power amplifier of claim 10 wherein the at least one bias voltage includes a first bias voltage provided to the first power switch and a second bias voltage provided to the second power switch.

12. The power amplifier of claim 11 wherein the first bias voltage is different than the second bias voltage.

13. The power amplifier of claim 12 wherein the first bias voltage has a different polarity than the second bias voltage.

14. The power amplifier of claim 1 wherein the first power switch is coupled in parallel with the second power switch.

15. The power amplifier of claim 14 further comprising an input-signal connection to receive the input signal, and wherein the input signal is provided to a first control connection of the first power switch and to a second control connection of the second power switch to drive the first power switch and the second power switch.

16. A method of operating a power amplifier comprising:
coupling an input-signal connection to a first power switch and a second power switch, the input-signal connection being configured to receive an input signal;
coupling an output-signal connection to the first power switch; and
selecting a size of the second power switch to improve a linearity of the first power switch, the size of the second power switch being different than a size of the first power switch.

17. The method of claim 16 further comprising selecting the size of the second power switch based on at least one parameter of the input signal.

18. The method of claim 17 wherein the at least one parameter includes at least one of a frequency, a voltage, or a power.

19. The method of claim 16 further comprising coupling a control connection of the second power switch to a bias-voltage connection, the bias-voltage connection being configured to provide a bias voltage having a value selected to improve the linearity of the first power switch.

20. A wireless device comprising:
an antenna to transmit or receive at least one radio-frequency (RF) signal; and
a power amplifier configured to amplify the at least one RF signal, the power amplifier comprising
a first power switch of a first type being configured to receive the at least one RF signal, amplify the at least one RF signal, and provide the amplified at least one RF signal to an output connection, and
a second power switch of a second type different than the first type, the second power switch being configured to improve a linearity of the power amplifier and being coupled to the output connection.
